(19) United States
(12) Patent Application Publication
(10) Pub. No.: US 2024/0321847 A1
(43) Pub. Date: Sep. 26, 2024

(54) SEMICONDUCTOR PACKAGE

(71) Applicant: SAMSUNG ELECTRONICS CO., LTD., SUWON-SI (KR)

(72) Inventor: Eunsu Lee, Suwon-si (KR)

(21) Appl. No.: 18/605,956

(22) Filed: Mar. 15, 2024

(30) Foreign Application Priority Data
Mar. 24, 2023 (KR) 10-2023-0039256

(51) Int. Cl. H01L 25/16; H01L 23/00; H01L 23/48; H01L 25/18; H10B 80/00

(52) U.S. Cl. CPC H01L 25/16; H01L 24/16; H01L 24/17; H01L 24/26; H01L 24/32; H01L 24/73; H01L 25/18; H10B 80/00; H01L 23/481; H01L 2224/16148; H01L 2224/16227; H01L 2224/1703; H01L 2224/26175; H01L 2224/32145; H01L 2224/32225; H01L 2224/73204; H01L 2924/1431; H01L 2924/1436; H01L 2924/182; H01L 2924/19106

(57) ABSTRACT

A semiconductor package includes a first substrate; a first chip structure disposed above the first substrate in a vertical direction; a second chip structure disposed above the first substrate and spaced apart from the first chip structure in a first horizontal direction perpendicular to the vertical direction; an underfill material layer disposed between the second chip structure and the first substrate; and a first protrusion extending from the first substrate in the vertical direction and extending in a second horizontal direction perpendicular to the vertical direction and the first horizontal direction along at least one side surface of the underfill material layer, where a side surface of the first protrusion contacts the underfill material layer.

### CROSS-REFERENCE TO RELATED APPLICATION

This application claims priority under 35 U.S.C. § 119 to Korean Patent Application No. 10-2023-0039256, filed on Mar. 24, 2023, in the Korean Intellectual Property Office, the disclosure of which is incorporated by reference herein in its entirety.

### BACKGROUND

Embodiments of the present disclosure relate to a semiconductor package, and more particularly, to a semiconductor package including an underfill material layer.

As the electronic product market evolves, there is a surging demand for portable devices. This surging demand has amplified the need for smaller and lighter electronic components. To achieve miniaturization and weight reduction, there is a need to have semiconductor packages integrated into electronic components to handle high-capacity data even as the size of the electronic components shrinks. To address this challenge, wafer-level and panel-level packaging technologies have been developed. These methods involve processing semiconductor packages at the wafer or panel level, and subsequently dividing the wafer or panel-level structures into individual packages.

### SUMMARY

Embodiments of the present disclosure provide a semiconductor package with a reduced size and improved productivity.

In addition, embodiments of the present disclosure are not limited to be directed to the above-mentioned problems, and may be directed to other problems that may be understood by those skilled in the art.

According to some embodiments, a semiconductor package includes a first substrate; a first chip structure disposed above the first substrate in a vertical direction; a second chip structure disposed above the first substrate and spaced apart from the first chip structure in a first horizontal direction perpendicular to the vertical direction; an underfill material layer disposed between the second chip structure and the first substrate; and a first protrusion extending from the first substrate in the vertical direction and extending in a second horizontal direction perpendicular to the vertical direction and the first horizontal direction along at least one side surface of the underfill material layer, where a side surface of the first protrusion contacts the underfill material layer.

According to some embodiments, a semiconductor package includes a first substrate; a first chip structure disposed above the first substrate in a vertical direction; a second chip structure disposed above the first substrate and spaced apart from the first chip structure in a first horizontal direction perpendicular to the vertical direction; a third chip structure disposed above the first substrate and spaced apart from the first chip structure in the first horizontal direction, where the second chip structure is located between the first chip structure and the third chip structure; an underfill material layer disposed between the second chip structure and the first substrate and between the third chip structure and the first substrate; a first protrusion extending in the vertical direction; and a second protrusion extending in the vertical direction, where the first protrusion surrounds the second chip structure on three sides in a plan view and the second protrusion surrounds the third chip structure on three sides in the plan view.

According to some embodiments, a semiconductor package includes a first substrate; a first chip structure disposed above the first substrate in a vertical direction; a second chip structure disposed above the first substrate and spaced apart from the first chip structure in a first horizontal direction perpendicular to the vertical direction; a third chip structure disposed above the first substrate and spaced apart from the first chip structure in the first horizontal direction with the second chip structure disposed therebetween; and an underfill material layer disposed between the second chip structure and the first substrate and between the third chip structure and the first substrate, where the first substrate includes a first protrusion extending in a vertical direction and a second protrusion, the first protrusion surrounds the second chip structure on three sides in a plan view and the second protrusion surrounds the third chip structure on three sides in the plan view, an empty space is formed between the second chip structure and the third chip structure, a height of each of the first protrusion and the second protrusion in the vertical direction is between 10 μm and 20 μm, the first chip structure is mounted on the first substrate through a first bump, the second chip structure includes a second substrate, where a semiconductor chip is mounted on the second substrate, the second substrate is mounted on the first substrate through a second bump located on the first substrate, the size of the second bump is smaller than the size of the first bump, and a passive component is formed on a lower portion of the second substrate.

### BRIEF DESCRIPTION OF THE DRAWINGS

FIG. 1 is a plan view schematically illustrating a semiconductor package according to some embodiments;

FIG. 2 is a cross-sectional view taken along line X1-X1′ of FIG. 1;

FIG. 3 is a cross-sectional view schematically illustrating a second chip structure according to some embodiments;

FIG. 4 is a schematic cross-sectional view of a semiconductor package according to some embodiments;

FIG. 5 is a plan view schematically illustrating a semiconductor package according to some embodiments;

FIG. 6 is a plan view schematically illustrating a semiconductor package according to some embodiments; and

FIGS. 7, 8, 9, and 10 are plan views schematically illustrating a method of manufacturing a semiconductor package according to some embodiments.

### DETAILED DESCRIPTION OF THE EMBODIMENTS

As semiconductor packages have been moving towards miniaturization and increased performance, methods have been explored to reduce the overall package size. One of the challenges in this area is that during the forming of underfill material layers between the substrate and individual chip structures, a dispensing area of a large size is required.

Embodiments of the present disclosure allow for forming the underfill material layer between a substrate and more than one chip structures simultaneously. By using simultaneous injection of the underfill material into two chip structures, the process of package formation becomes more streamlined. Accordingly, embodiments of the present disclosure provide a method for significantly reducing the dispensing area required for forming the underfill material layer, leading to a more compact semiconductor package design.

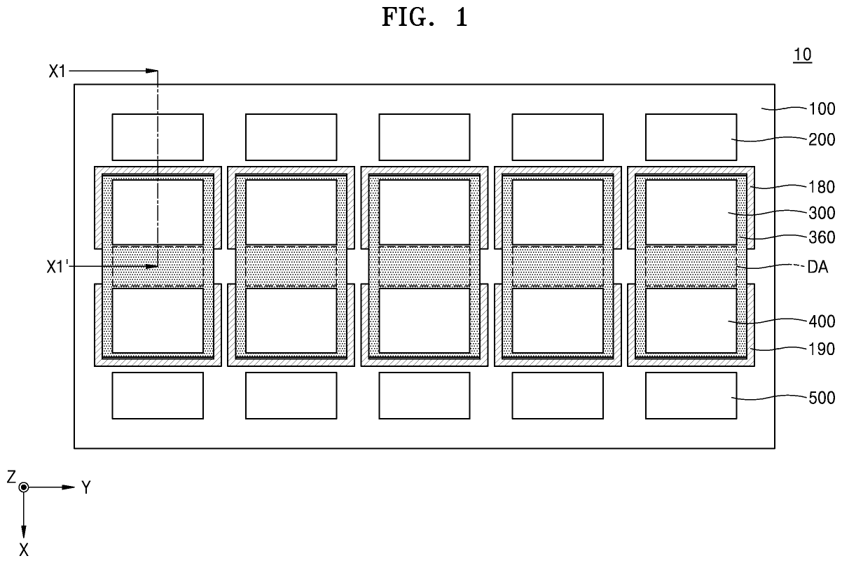

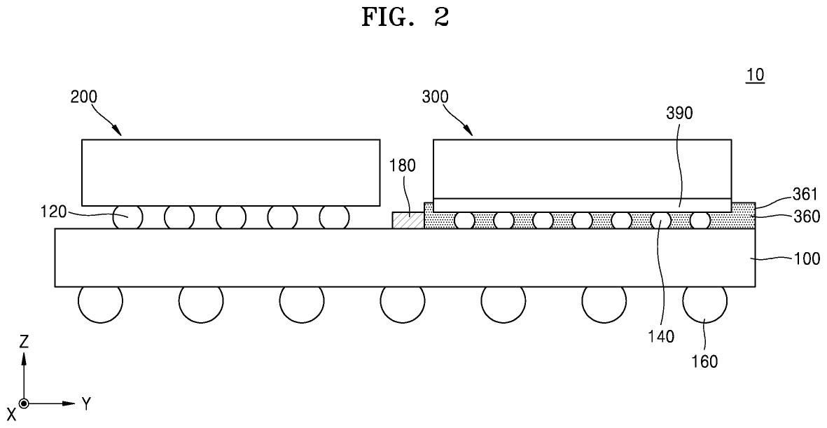

FIG. 1 is a plan view schematically illustrating a semiconductor package according to some embodiments. FIG. 2 is a cross-sectional view taken along line X1-X1′ of FIG. 1.

Referring to FIGS. 1 and 2, a semiconductor package 10 may include a first substrate 100, first chip structures 200, second chip structures 300, third chip structures 400, and fourth chip structures 500. The first substrate 100 may be a substrate. The first chip structures 200, the second chip structures 300, the third chip structures 400, and the fourth chip structures 500 may be mounted on the first substrate 100. However, embodiments of the present disclosure are not limited thereto, and at least one chip structure of the first to fourth chip structures 200, 300, 400, and 500 may be mounted on the first substrate 100, and in some cases, five or more than five chip structures may be mounted on the first substrate 100.

In addition, the first substrate 100 may be formed based on, for example, a ceramic substrate, a printed circuit board (PCB), an organic substrate, etc., and may include an interposer substrate. Examples of the substrate are described below. According to some embodiments, the first substrate 100 may include a redistribution structure.

External connection terminals 160 may be disposed on a lower surface of the first substrate 100. External connection terminals 160 may be electrically connected to an external connection device through a pad formed on the lower surface of the first substrate 100. The external connection device may include, for example, a motherboard PCB, etc., and may include a package substrate as is described below. According to some embodiments, each of the external connection terminals 160 may form as a solder ball. Also, in some embodiments, each of the external connection terminals 160 may have a structure including a pillar and a solder. Each of the external connection terminals 160 may include at least one of copper (Cu), silver (Ag), gold (Au), or tin (Sb).

In the following drawings, the X-axis direction and the Y-axis direction may be in directions perpendicular to each other and parallel to an upper surface of the first substrate 100. The Z-axis direction may indicate a direction perpendicular to the upper or lower surface of the first substrate 100. In some cases, the Z-axis direction may be perpendicular to an X-Y plane.

In some examples, the X-axis may be in a first horizontal direction, the Y-axis may be in a second horizontal direction perpendicular to the first horizontal direction, and the Z-axis may be in a vertical direction perpendicular to the first horizontal direction and the second horizontal direction.

The first chip structures 200 may be mounted on the upper surface of the first substrate 100. In some examples, the first chip structures 200 may be mounted on the first substrate 100 in a vertical direction. According to some embodiments, a plurality of first chip structures 200 may be provided, and may be spaced apart from each other in the second horizontal direction Y and disposed in a line on the upper surface of the first substrate 100. The plurality of first chip structures 200 may be disposed adjacent to one side surface of the first substrate 100.

According to some embodiments, each of the first chip structures 200 may include at least one semiconductor chip. For example, the semiconductor chip may be a memory chip, for example, a volatile memory chip such as a dynamic random access memory (DRAM) chip or a static random access memory (SRAM) chip, or a non-volatile memory chip such as a phase-change random access memory (PRAM) chip, a magnetoresistive random access memory (MRAM) chip, a ferroelectric random access memory (FeRAM) chip, or a resistive random access memory (RRAM) chip. However, the semiconductor chip is not limited thereto, and may include a microprocessor such as a central processing unit (CPU), a graphics processing unit (GPU), or an application processor (AP), an analog device, or a logic chip such as a digital signal processor.

According to some embodiments, the first chip structures 200 may be disposed above the upper surface of the first substrate 100. For example, the first chip structures 200 may be mounted on the first substrate 100 using a flip chip method through first bumps 120. According to some embodiments, an underfill material layer surrounding the first bumps 120 may be disposed between each of the first chip structures 200 and the first substrate 100. However, the first chip structure 200 is not limited thereto, and may be attached to the first substrate 100 through a die attach film and electrically connected to the first substrate 100 through a wire, etc.

The second chip structures 300 may be disposed above the first substrate 100 and spaced apart from each other in the first horizontal direction X. In some examples, the horizontal direction X may be perpendicular to the vertical direction. According to some embodiments, a plurality of second chip structures 300 may be provided, and may be spaced apart from each other in the second horizontal direction Y. In some examples, the horizontal direction Y may be perpendicular to the vertical direction. Also, the plurality of second chip structures 300 may be respectively spaced apart from the plurality of first chip structures 200 in the first horizontal direction X.

The second chip structures 300 may be mounted on the first substrate 100 in the flip chip method through second bumps 140. In some examples, an underfill material layer 360 surrounding the second bumps 140 may be formed between each of the second chip structures 300 and the first substrate 100. Underfill material refers to a type of adhesive used in electronic packaging, particularly in flip chip bonding processes. The underfill may be used to provide mechanical reinforcement, improve thermal performance, and enhance the reliability of the assembly. In some cases, underfill material is non-conductive and is provided to fill space between chip structures and substrates. However, the embodiments of the present disclosure may not be limited thereto. For example, the underfill material layer 360 may include conductive underfills including conductive fillers such as silver or gold particles to provide additional electrical connectivity. The underfill material layer 360 may include, for example, an epoxy resin formed by a capillary under-fill method. For example, the epoxy resin may be dispensed around the edges of the chip and then, and due to capillary action, the epoxy resin may be drawn into the gaps between the chip and the substrate. For example, the capillary under-fill method may lead to uniform distribution and provide a consistent bond between the chip and the substrate. However, in some embodiments, a molding layer may directly fill a gap between each of the second chip structures 300 and the first substrate 100 through a molded under-fill process. In some examples, the bumps 140 may form boundaries of the underfill material layer 360.

As is described below, the underfill material layer 360 may be filled between each of the second chip structures 300 and the first substrate 100 through a dispensing area DA. In semiconductor manufacturing, the dispensing area DA may refer to the area on a semiconductor package or chip where materials, for example the underfill, are applied or dispensed.

According to some embodiments, each of the second chip structures 300 may include at least one semiconductor chip, and the semiconductor chip may include a logic chip. The logic chip may be a microprocessor such as a CPU, GPU, or AP, an analog device, or a digital signal processor. However, the semiconductor chip is not limited thereto, and may include a volatile memory chip such as DRAM and SRAM, or a non-volatile memory chip such as PRAM, MRAM, FeRAM, and RRAM.

In some embodiments, each of the second chip structures 300 may further include a second substrate 390. A semiconductor chip may be mounted on an upper surface of the second substrate 390, and the second bumps 140 may be mounted on a lower surface of the second substrate 390. According to some embodiments, each of the second bumps 140 may have a smaller volume than that of each of the first bump 120.

The third chip structures 400 may be disposed above the first substrate 100 and respectively spaced apart from the first chip structures 200 in the first horizontal direction X, where the second chip structures 300 may be disposed between the first substrate 100 and the first chip structure 200. According to some embodiments, a plurality of third chip structures 400 may be provided, and may be spaced apart from each other in the second horizontal direction Y. According to some embodiments, the third chip structure 400 may be respectively spaced apart from the second chip structure 300 by 500 μm or more in the first horizontal direction X. 500 μm may be the minimum value required to simultaneously inject the underfill material into each of the second chip structures 300 and the third chip structures 400.

According to some embodiments, the third chip structures 400 may be substantially the same as the second chip structures 300, respectively. However, the third chip structures 400 are not limited thereto, and may be different types of chip structures from the second chip structures 300.

According to some embodiments, distances between the second chip structures 300 and the third chip structures 400 in the first horizontal direction X may be respectively greater than distances between the first chip structures 200 and the second chip structures 300 in the first horizontal direction X. An underfill material constituting the underfill material layer 360 may be provided between the second chip structures 300 and the third chip structures 400. For example, the underfill material may be injected through the space between the second chip structures 300 and the third chip structures 400. The area into which the underfill material is injected may be referred to as the dispensing area DA. The underfill material injected through the dispensing area DA may fill between the second chip structure 300 and the first substrate 100 and fill between the third chip structure 400 and the first substrate 100. Accordingly, the dispensing area DA is provided in such way that, with a single injection, the underfill material layer 360 fills simultaneously both the space between each of the second chip structures 300 and the first substrate 100, and the space between each of the third chip structures 400 and the first substrate 100. In some examples, the second chip structures 300 and the third chip structures 400 may share the dispensing area DA into which the underfill material is injected.

The underfill material layer 360 formed by a single injection between each of the second chip structures 300 and the first substrate 100 and between each of the third chip structures 400 and the first substrate 100 through the dispensing area DA may be separated in the first horizontal direction X through a dicing process. For example, a sidewall 361 of the underfill material layer 360 formed by dicing may form a substantially right angle to the upper surface of the first substrate 100. Here, the sidewall 361 may be referred to as a cross section formed by separating the underfill material layer 360 simultaneously formed between each of the second chip structures 300 and the first substrate 100 and between each of the third chip structures 400 and the first substrate 100 through a dicing process in the first horizontal direction X. Accordingly, the sidewall 361 of the underfill material layer 360 formed between each of the second chip structures 300 and the first substrate 100 may be faced opposite to a sidewall of the underfill material layer 360 facing the first chip structure 200.

As the second chip structures 300 and the third chip structures 400 share the dispensing area DA, an area required to form the underfill material layer 360 on each of the second chip structures 300 and the third chip structures 400 may be reduced, and thus, more chip structures may be mounted on the first substrate 100, and the size of the semiconductor package 10 may be reduced. In addition, the underfill material layers 360 are simultaneously formed on the lower portions of each of the second chip structures 300 and the third chip structures 400, and thus, a process time taken to manufacture the semiconductor package 10 may be shortened.

The fourth chip structures 500 may be respectively spaced apart from the second chip structures 300 in the first horizontal direction X, where the third chip structures 400 may be disposed between the fourth chip structures 500 and the second chip structures 300. According to some embodiments, the fourth chip structures 500 may be substantially the same as the first chip structures 200, respectively. However, the fourth chip structures 500 are not limited thereto, and may be different types of chip structures from the first chip structures 200.

The first substrate 100 may include first protrusions 180 protruding from the upper surface thereof in the vertical direction Z. Protrusions 180 and 190 refer to structures that extend or stick out from a surface. In semiconductor packages, a protrusion may be a raised part or bump on the first substrate 100. In some examples, the protrusion surrounds at least one side of the underfill layer 360. In some examples, the protrusion is adjacent to at least one side of the underfill layer 360. In some examples, a protrusion may be a boundary or a wall for the underfill material to contain, shape, or direct the underfill material. Each of the first protrusions 180 may surround at least one side surface of the underfill material layer 360 disposed between each of the second chip structures 300 and the first substrate 100. For example, the first protrusions 180 may be respectively formed between the first chip structures 200 and the second chip structures 300. According to some embodiments, the underfill material layer 360 may be formed as the underfill material is provided between the first substrate 100 and each of the second chip structures 300 and hardened. In some examples, the flow of the underfill material may be restricted by the first protrusions 180. Accordingly, each of the first protrusions 180 may prevent the underfill material layer 360 from being formed even between each of the first chip structures 200 and the first substrate 100. The underfill material layer 360 formed on the first substrate 100 may be in contact with the side surface of each of the first protrusions 180.

According to some embodiments, each of the first protrusions 180 may surround each of the second chip structures 300 on three side surfaces in a plan view. For example, each of the first protrusions 180 may surround each of the second chip structures 300 on the three side surfaces excluding an area in which each of the second chip structures 300 and each of the third chip structures 400 face each other. For example, each of the first protrusions 180 may have a shape surrounding three of four side surfaces of each of the second chip structures 300 excluding a side surface farthest from each of the first chip structures 200. As each of the first protrusions 180 surrounds each of the second chip structures 300 on the three side surfaces in a plan view, the underfill material layer 360 formed between each of the second chip structures 300 and the first substrate 100 may extend only to a point where the first protrusion 180 is formed.

According to some embodiments, a height of each of the first protrusions 180 in the vertical direction Z may be between about 10 μm and about 20 μm. In some embodiments, an upper surface of each of the first protrusions 180 may be at a lower level than that of the lower surface of each of the second chip structures 300 in the vertical direction Z.

The sidewall 361 of the underfill material layer 360 may be formed at least 10 μm above the lower surface of each of the second chip structures 300 in the vertical direction Z. For example, when each of the second chip structures 300 includes the second substrate 390, the sidewall 361 of the underfill material layer 360 may be formed at least 10 μm above a lower surface of the second substrate 390 in the vertical direction Z. For example, a level of the sidewall 361 in the vertical direction Z may be at least 10 μm higher than a level of the lower surface of the second substrate 390 in the vertical direction Z.

The underfill material introduced into the dispensing area DA is confined within a specific region by the first protrusions 180. According to some embodiments, with the same amount of underfill material used, the sidewall 361 of the underfill material layer 360 might exhibit a higher vertical elevation in direction Z in the absence of the first protrusion.

According to some embodiments, the first substrate 100 may further include second protrusions 190. Each of the second protrusions 190 may surround at least one side surface of the underfill material layer 360 disposed between each of the third chip structures 400 and the first substrate 100. For example, the second protrusions 190 may be formed between the third chip structures 400 and the fourth chip structures 500, respectively. Accordingly, each of the second protrusion 190 may prevent the underfill material layer 360 from being formed even between each of the fourth chip structures 500 and the first substrate 100.

According to some embodiments, each of the second protrusions 190 may be configured to surround each of the third chip structures 400 on three side surfaces in a plan view. For example, each of the second protrusions 190 may be configured to surround each of the third chip structures 400 on the three side surfaces excluding an area in which each of the second chip structures 300 and each of the third chip structures 400 face each other. For example, each of the second protrusions 190 may have a shape surrounding three of four side surfaces of each of the third chip structures 400 excluding a side surface farthest from each of the fourth chip structures 500. As each of the second protrusions 190 surrounds each of the third chip structures 400 on the three side surfaces, the underfill material layer 360 formed between each of the third chip structures 400 and the first substrate 100 may extend only to a point where the second protrusion 190 is formed.

The first protrusions 180 and the second protrusions 190 may confine the underfill material provided through the dispensing area DA, and a shape of the underfill material layer 360 may be substantially derived from shapes of the first protrusions 180 and the second protrusions 190.

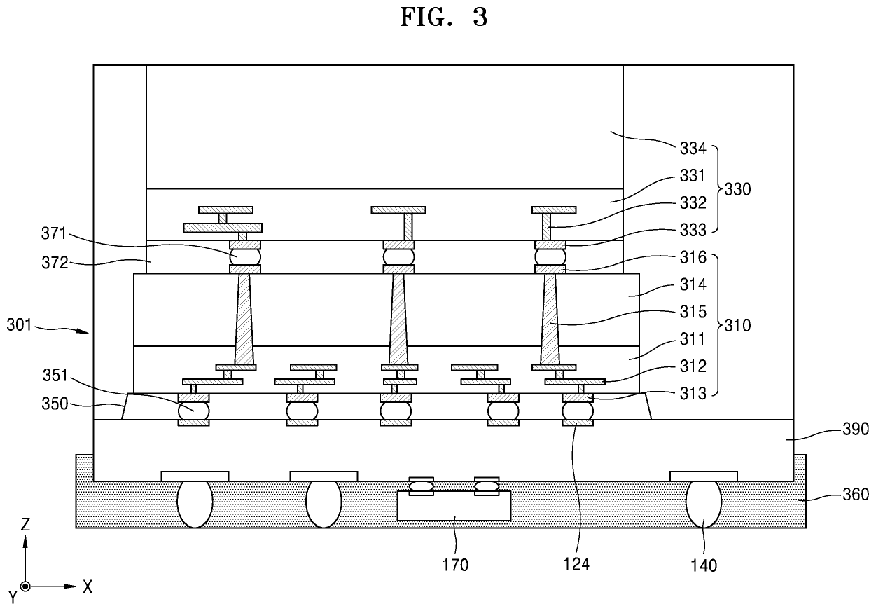

FIG. 3 is a cross-sectional view schematically illustrating a second chip structure according to some embodiments.

Referring to FIG. 3, a second chip structure 301 may include the second substrate 390, a lower semiconductor chip 310, and an upper semiconductor chip 330. According to some embodiments, the second substrate 390 may be mounted on the first substrate 100 (see FIG. 2) through the second bumps 140. A passive component 170 may be mounted on a lower surface of the second substrate 390. According to some embodiments, the passive component 170 may be a surface-mount device (SMD), a capacitor, or a resistor. A connection terminal of the passive component 170 may be provided on an upper surface of the passive component 170, and a conductive connection pillar for electrical connection between the passive component 170 and the second substrate 390 may be attached onto the connection terminal of the passive component 170. For example, the connection pillar may include a conductive material such as copper (Cu) or aluminum (Al). However, embodiments of the present disclosure are not limited thereto.

The lower semiconductor chip 310 and the upper semiconductor chip 330 may be mounted on the second substrate 390. According to some embodiments, the lower semiconductor chip 310 and the upper semiconductor chip 330 may include a logic chip and a memory chip, but the lower semiconductor chip 310 and the upper semiconductor chip 330 are not limited thereto, and may include two logic chips or two memory chips.

The lower semiconductor chip 310 may include a first semiconductor substrate 314, a first device layer 311, first bump pads 313, and second bump pads 316. The first semiconductor substrate 314 may have upper and lower surfaces that are faced opposite to each other. The upper surface thereof may face the upper semiconductor chip 330 and the lower surface thereof may face the second substrate 390. The upper surface thereof may be referred to as an inactive surface, and the lower surface thereof may be referred to as an active surface.

The first semiconductor substrate 314 may include silicon (Si), for example, crystalline silicon, polycrystalline silicon, or amorphous silicon. Alternatively, the first semiconductor substrate 314 may include a semiconductor element such as germanium (Ge) or a compound semiconductor such as silicon carbide (SiC), gallium arsenide (GaAs), indium arsenide (InAs), and indium phosphide (InP). For example, the first semiconductor substrate 314 may have a silicon on insulator (SOI) structure. For example, the first semiconductor substrate 314 may include a buried oxide (BOX) layer. The first semiconductor substrate 314 may include a conductive area, for example, a well doped with impurities or a structure doped with impurities. Also, the first semiconductor substrate 314 may have various device isolation structures such as a shallow trench isolation (STI) structure.

The first device layer 311 may include first wiring patterns 312 electrically connected to a plurality of semiconductor devices formed on the first semiconductor substrate 314. Each of the first wiring patterns 312 includes a metal wiring layer and a via plug. For example, these wiring patterns 312 may have a multilayered design where more than one metal wiring layers and more than one via plugs are stacked alternately. According to some embodiments, the first device layer 311 may be formed on the lower surface of the first semiconductor substrate 314 which is the active surface. The first device layer 311 may be located below the first semiconductor substrate 314. The first semiconductor substrate 314 may be spaced apart from the second substrate 390 in the vertical direction Z, where first device layer 311 may be disposed between the first semiconductor substrate 314 and the second substrate 390. The lower semiconductor chip 310 may include through electrodes 315 penetrating at least a part of the first device layer 311 and the first semiconductor substrate 314.

The first bump pads 313 may be disposed on a lower surface of the first device layer 311 and may be electrically connected to the first wiring patterns 312 inside the first device layer 311, respectively. The first bump pads 313 may be electrically connected to the through electrodes 315 through the first wiring patterns 312, respectively.

The through electrodes 315 may pass through parts of the first semiconductor substrate 314 and the first device layer 311. The through electrodes 315 may extend in the vertical direction Z from the first device layer 311 toward the upper surface of the first semiconductor substrate 314 and may be electrically connected to the first wiring patterns 312 provided in the first device layer 311, respectively. Accordingly, the first bump pads 313 may be electrically connected to the through electrodes 315 through the first wiring patterns 312, respectively. The through electrodes 315 may have a tapered shape, with the width in the horizontal direction either decreasing or increasing as the vertical direction level rises. At least a part of each of the through electrodes 315 may have a pillar shape. The through electrodes 315 may include a through silicon via (TSV).

The second bump pads 316 may be formed on the upper surface of the first semiconductor substrate 314, For example, on the inactive surface of the first semiconductor substrate 314. The second bump pads 316 may include substantially the same material as the first bump pads 313.

An underfill layer 350 may be disposed between the lower semiconductor chip 310 and the second substrate 390. The underfill layer 350 may be disposed between the lower semiconductor chip 310 and the second substrate 390 and surround third bumps 351. The underfill layer 350 may include, for example, an epoxy resin formed by a capillary under-fill method. For example, the epoxy resin may be dispensed around the edges of the chip and then, and due to capillary action, the epoxy resin may be drawn into the gaps between the chip and the substrate. For example, the capillary under-fill method may lead to uniform distribution and provide a consistent bond between the chip and the substrate. In some embodiments, the underfill layer 350 may cover at least a part of a side surface of the lower semiconductor chip 310.

The third bumps 351 may be respectively disposed to contact the first bump pads 313. The third bumps 351 may be disposed to contact first upper pads 124 disposed on the second substrate 390, respectively. The third bumps 351 may electrically connect the third chip structure 300 to the second substrate 390. Through the third bumps 351, the lower semiconductor chip 310 may receive at least one of a control signal, a power signal, and a ground signal for operation of the lower semiconductor chip 310 from the outside, receive a data signal to be stored in the lower semiconductor chip 310 from the outside, or provide data stored in the lower semiconductor chip 310 to the outside. For example, each of the third bumps 351 may include a pillar structure, a ball structure, or a solder layer.

The upper semiconductor chip 330 may include a second semiconductor substrate 334, a second device layer 331, and third bump pads 333. The upper semiconductor chip 330 may have the same or similar characteristics as those of the lower semiconductor chip 310, and thus, differences from the lower semiconductor chip 310 are mainly described.

The second semiconductor substrate 334 may have lower and upper surfaces that are faced opposite to each other. The lower surface thereof may face the lower semiconductor chip 310 and the upper surface thereof may be a surface faced opposite to the lower surface. The upper surface thereof may be referred to as an inactive surface, and the lower surface thereof may be referred to as an active surface.

The second device layer 331 may include second wiring patterns 332 electrically connected to a plurality of semiconductor devices formed on the second semiconductor substrate 334, respectively. Each of the first wiring patterns 332 includes a metal wiring layer and a via plug. For example, these wiring patterns 332 may have a multilayered design where more than one metal wiring layers and more than one via plugs are stacked alternately.

According to some embodiments, the second device layer 331 may be formed on the lower surface of the second semiconductor substrate 334, which is the active surface. The second device layer 331 may be located below the second semiconductor substrate 334. The second semiconductor substrate 334 may be spaced apart from the lower semiconductor chip 310 in the vertical direction Z, where the second device layer 331 may be disposed between second semiconductor substrate 334 and the lower semiconductor chip 310.

The third bump pads 333 may be disposed on a lower surface of the second device layer 331 and may be electrically connected to the second wiring patterns 332 inside the second device layer 331, respectively.

Fourth bumps 371 may be located between the lower semiconductor chip 310 and the upper semiconductor chip 330. The fourth bumps 371 may electrically connect the lower semiconductor chip 310 to the upper semiconductor chip 330.

The fourth bumps 371 may be respectively disposed to contact the second bump pads 316 and the third bump pads 333. The upper semiconductor chip 330 may be electrically connected to the lower semiconductor chip 310 through the fourth bumps 371 disposed between the lower semiconductor chip 310 and the upper semiconductor chip 330. The upper semiconductor chip 330 uses the fourth bumps 371 to facilitate several functions. For example, the upper semiconductor chip 330 may receive signals necessary for its operation, which include at one of a control signal, a power signal, and a ground signal. In some examples, the chip can also receive a data signal and store the data signal it. In some examples, the upper semiconductor chip 330 can output stored data through the fourth bumps 371.

As a result, the second chip structure 301 may have a 3D-IC structure in which the lower and upper semiconductor chips 310 and 330 are stacked in the vertical direction and connected to each other through the through electrodes 315. However, the type of the second chip structure 301 is not limited thereto, and any chip structure that requires fixation to an external substrate, for example, the first substrate 100 (see FIG. 2) through the underfill material layer 360 is sufficient.

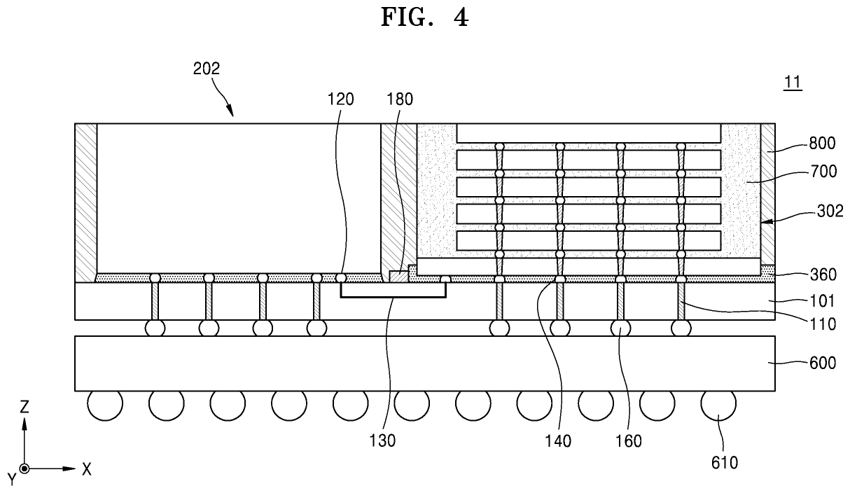

FIG. 4 is a schematic cross-sectional view of a semiconductor package according to some embodiments.

Referring to FIG. 4, the semiconductor package 11 may include a first substrate 101, a package substrate 600, a first chip structure 202, and a second chip structure 302.

The first substrate 101 may be mounted on the package substrate 600. The first substrate 101 may be electrically connected to the package substrate 600 through the external connection terminals 160. The external connection terminals 160 may physically and electrically connect the first substrate 101 to the package substrate 600.

According to some embodiments, the first substrate 101 may include an interposer substrate. For example, the first substrate 101 may be configured to electrically connect the first chip structure 202 to the second chip structure 302, and electrically connect each of the first chip structure 202 and the second chip structure 302 to the package substrate 600. According to some embodiments, the first substrate 101 may be a Si interposer substrate having a 2.5D package structure. In some examples, the semiconductor package 11 may be referred to as a 2.5D package having a structure in which heterogeneous semiconductor chips are electrically connected to each other through an interposer substrate.

The first substrate 101 may include a base layer and a redistribution structure disposed on the base layer. The first substrate 101 may electrically connect the first chip structure 202 to the second chip structure 302 through a redistribution pattern 130. The redistribution pattern 130 may be formed in the redistribution structure. The through electrodes 110 may be electrically connected to the redistribution pattern 130 of the redistribution structure. Accordingly, the first substrate 101 may electrically connect the first chip structure 202 and the second chip structure 302 to the package substrate 600 through the through electrodes 110 formed in the base layer.

The package substrate 600 may include at least one wiring layer. The first substrate 101 may be mounted on the package substrate 600. In some cases, wirings may be formed in more than one layers where the wirings may be connected to each other through vias. In some embodiments, the package substrate 600 may include through electrodes directly connecting substrate pads on upper and lower surfaces thereof. Although not shown, protective layers such as solder resist may be formed on the upper and lower surfaces of the package substrate 600. The substrate pads of the package substrate 600 may be connected to wirings of a wiring layer and may be exposed from the protective layers.

External connection terminals 610 may be disposed on the lower surface of the package substrate 600. The external connection terminals 610 may be electrically connected to an external device, for example, a motherboard. The external connection terminals 610 may be electrically connected to the package substrate 600. The external connection terminals 610 may be electrically connected to wiring patterns formed in the package substrate 600 through the substrate pad attached to the lower surface of the package substrate 600. The external connection terminals 610 may electrically and physically connect the semiconductor package 11 to an external device on which the semiconductor package 11 is mounted.

According to some embodiments, each of the first chip structure 202 and the second chip structure 302 may include at least one semiconductor chip. For example, the first chip structure 202 may include a logic chip. According to some embodiments, the first chip structure 202 may be an ASIC package including a logic chip.

The second chip structure 302 may include a plurality of semiconductor chips stacked in one direction. The one direction may be the vertical direction Z. According to some embodiments, the semiconductor chips may be high bandwidth memory (HBM) DRAM chips used in an HBM package. According to some embodiments, the second chip structure 302 may include a base chip located at the lowest portion and semiconductor chips stacked in the vertical direction Z on the base chip, and a through electrode may be formed inside each of the base chip and the semiconductor chips. In some embodiments, the base chip may include logic devices, and the semiconductor chips may include DRAM devices.

The second chip structure 302 may be mounted on the first substrate 101 by second bumps 140, and the second bumps 140 may be fixed by the underfill material layer 360. The underfill material layer 360 may be located between the second chip structure 302 and the first substrate 101.

The first substrate 101 may include the first protrusion 181 extending in the vertical direction Z. The first protrusion 181 may surround at least one side surface of the second chip structure 302. In this case, the first protrusion 181 may surround three of four side surfaces of the second chip structure 302 excluding a side surface located farthest from the first chip structure 202. For example, the first protrusion 181 may form boundary of the second chip structure 302 on at least on side.

The semiconductor chips inside the second chip structure 302 may be sealed by a first molding member 700. The first molding member 700 may include a thermosetting resin such as epoxy resin, a thermoplastic resin such as polyimide, or a resin including a reinforcing material such as an inorganic filler in the thermosetting resin and the thermoplastic resin, specifically, Ajinomoto Build-up Film (ABF), FR-4, BT etc., but is not limited thereto, and the first molding member 700 may include a molding material such as an epoxy mold compound (EMC) or a photosensitive material such as photoimagable encapsulant (PIE). In some embodiments, a part of the first molding member 700 may include an insulating material such as a silicon oxide layer, a silicon nitride layer, or a silicon oxynitride layer.

A second molding member 800 may surround the first chip structure 202 and the second chip structure 302 on the first substrate 101. The second molding member 800 may cover the upper surface of the first substrate 101 and a sidewall of each of the first chip structure 202 and the second chip structure 302. In some embodiments, the second molding member 800 may cover the sidewall of each of the first chip structure 202 and the second chip structure 302, but not the upper surface of each of the first chip structure 202 and the second chip structure 302. The second molding member 800 may include an epoxy resin and an inorganic filler and/or an organic filler contained in the epoxy resin. In some embodiments, the second molding member 800 may include an EMC.

According to some embodiments, the upper surfaces of the first chip structure 202 and the second chip structure 302 may be at the same level in the vertical direction Z. For example, the upper surfaces of the first chip structure 202 and the second chip structure 302 may be located at substantially the same height. According to some embodiments, an upper surface of the second molding member 800 may be coplanar with the upper surfaces of the first chip structure 202 and the second chip structure 302.

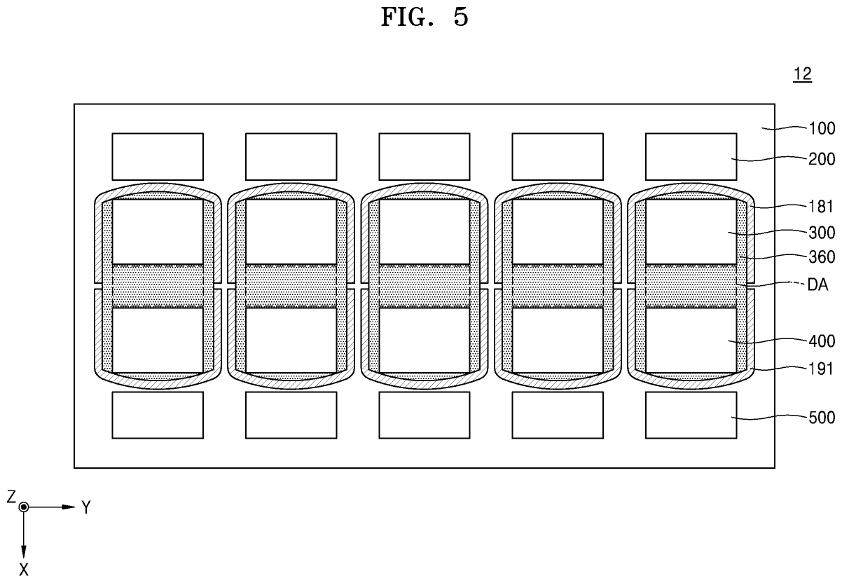

FIG. 5 is a plan view schematically illustrating a semiconductor package according to some embodiments.

Referring to FIG. 5, the semiconductor package 12 may include the first substrate 100, the first chip structures 200, the second chip structures 300, the third chip structures 400, and the fourth chip structures 500.

The first substrate 100 may include the first protrusions 181 and second protrusions 191 protruding from an upper surface of the first substrate 100 in the vertical direction Z. According to some embodiments, each of the first protrusions 181 may surround the underfill material layer 360 on at least one side surface of the underfill material layer 360. The underfill material layer 360 may be disposed between each of the second chip structures 300 and the first substrate 100. Each of the second protrusions 191 may surround the underfill material layer 360 on at least one side surface of the underfill material layer 360. The underfill material layer 360 may disposed between each of the third chip structures 400 and the first substrate 100.

Each of first protrusions 181 may surround each of the second chip structures 300 on three side surfaces. For example, each of the first protrusions 181 may surround each of the second chip structures 300 on the three side surfaces excluding an area in which each of the second chip structures 300 and each of the third chip structures 400 face each other. For example, each of the first protrusions 181 may have a shape surrounding three of four side surfaces of each of the second chip structures 300 excluding a side surface farthest from the first chip structure 200. In some examples In some examples, at least one side of the first protrusions 181 may be curved in a plan view. For example, when viewing the first protrusions 181 in the vertical direction Z, at least a part of each of the first protrusions 181 may have a curved shape.

Each of the second protrusions 191 may surround each of the third chip structures 400 on three side surfaces in a plan view. For example, each of the second protrusions 191 may surround the third chip structures 400 on the three side surfaces, excluding an area in which each of the second chip structures 300 and each of the third chip structures 400 face each other. For example, each of the second protrusions 191 may have a shape surrounding three of four side surfaces of each of the third chip structures 400 excluding a side surface farthest from each of the fourth chip structures 500. In some examples, at least one side of the second protrusions 191 may be curved in a plan view. For example, when viewing the second protrusions 191 in the vertical direction Z, at least a part of each of the second protrusions 191 may have a curved shape.

When at least a part of the horizontal cross section of each of the first protrusions 181 and each of the second protrusions 191 has the curved shape, the underfill material layer 360 may be evenly formed according to the first protrusions 181 and the second protrusions 191, and may prevent underfill materials from aggregating at the corners of the first protrusions 181 and the second protrusions 191.

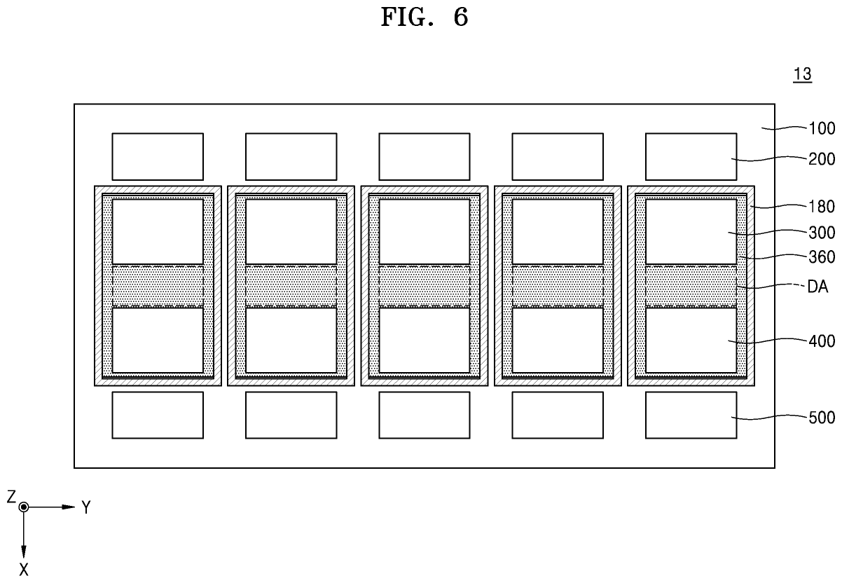

FIG. 6 is a plan view schematically illustrating a semiconductor package according to some embodiments.

Referring to FIG. 6, the semiconductor package 13 may include the first substrate 100, the first chip structures 200, the second chip structures 300, the third chip structures 400, and the fourth chip structures 500.

The first substrate 100 may include first protrusions 182 protruding from an upper surface thereof in the vertical direction Z. According to some embodiments, each of the first protrusions 182 may be integrally formed to surround each of the second chip structures 300 and each of the third chip structures 400. For example, each of the first protrusions 182 may be configured to surround each of the second chip structures 300 and each of the third chip structures 400 by a single injection of the underfill materials. In some cases, in the semiconductor package 10 described with reference to FIGS. 1 and 2, each of the first protrusions 180 and each of the second protrusions 190 may be integrally formed to completely surround each of the second chip structures 300 and each of the third chip structures 400.

When each of the first protrusions 182 surrounds each of the second chip structures 300 and each of the third chip structures 400 by a single injection of the underfill materials, an underfill material provided through the dispensing area DA be prevented from overflowing outside each of the first protrusions 182. In addition, as each of the first protrusions 182 is formed by a single injection of the underfill materials, the process time may be shortened.

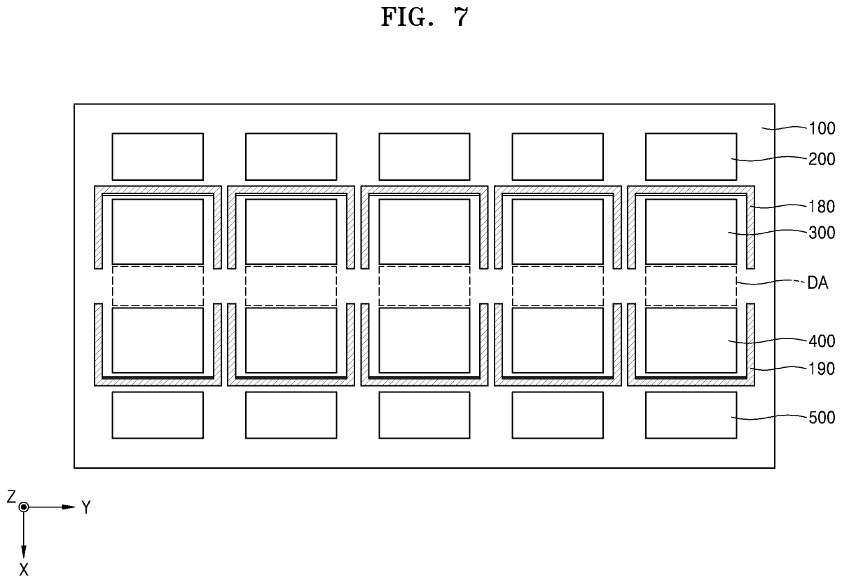

FIGS. 7 to 10 are plan views schematically illustrating a method of manufacturing a semiconductor package according to some embodiments.

The method of manufacturing the semiconductor package according to some embodiments is described with reference to FIGS. 7 to 10.

Referring to FIG. 7, the first chip structures 200, the second chip structures 300, the third chip structures 400, and the fourth chip structures 500 are disposed above the first substrate 100 on which the first protrusions 180 and the second protrusions 190 are formed.

According to some embodiments, the first protrusion 180 and the second protrusions 190 may have a shape with one surface open when viewed in the vertical direction Z, and an open area of the first protrusion 180 and an open area of the second protrusion 190 may be faced opposite to each other.

According to some embodiments, the first chip structures 200, the second chip structures 300, the third chip structures 400, and the fourth chip structures 500 may be respectively spaced apart from each other in the first horizontal direction X. In this case, the first chip structures 200 may be respectively disposed outside the first protrusions 180, and the second chip structures 300 may be respectively disposed inside the first protrusions 180. The third chip structures 400 may be respectively disposed inside the second protrusions 190, and the fourth chip structure 500 may be respectively disposed outside the second protrusions 190. Accordingly, the first protrusions 180 may be respectively located between the first chip structures 200 and the second chip structures 300, the second protrusions 190 may be respectively located between the third chip structures 400 and the fourth chip structures 500, and gaps may be respectively formed between the second chip structures 300 and the third chip structures 400. Each of the gaps between the second chip structures 300 and the third chip structures 400 may be a dispensing area DA. An underfill material may be injected into the space between the second chip structures 300 and the third chip structures 400 through the dispensing area DA.

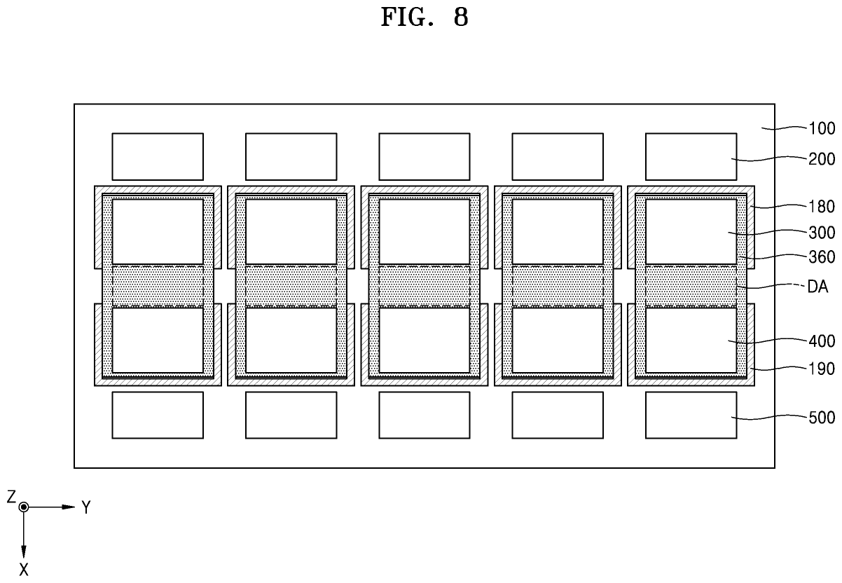

Referring to FIG. 8, the underfill material forming the underfill material layer 360 is injected through the dispensing area DA.

The underfill material injected into the dispensing area DA may be provided between each of the second chip structures 300 and the first substrate 100 and between each of the third chip structures 400 and the first substrate 100. The flow of the underfill material provided between each of the second chip structures 300 and the first substrate 100 and between each of the third chip structures 400 and the first substrate 100 may be restricted by the first protrusions 180 and the second protrusions 190. Accordingly, the underfill material may be cured inside the first protrusions 180 and the second protrusions 190 without flowing to the outside of the first protrusions 180 and the second protrusions 190.

As a result, the underfill material layer 360 formed by curing the underfill material may be formed simultaneously between each of the second chip structures 300 and the first substrate 100 and between each of the third chip structures 400 and the first substrate 100.

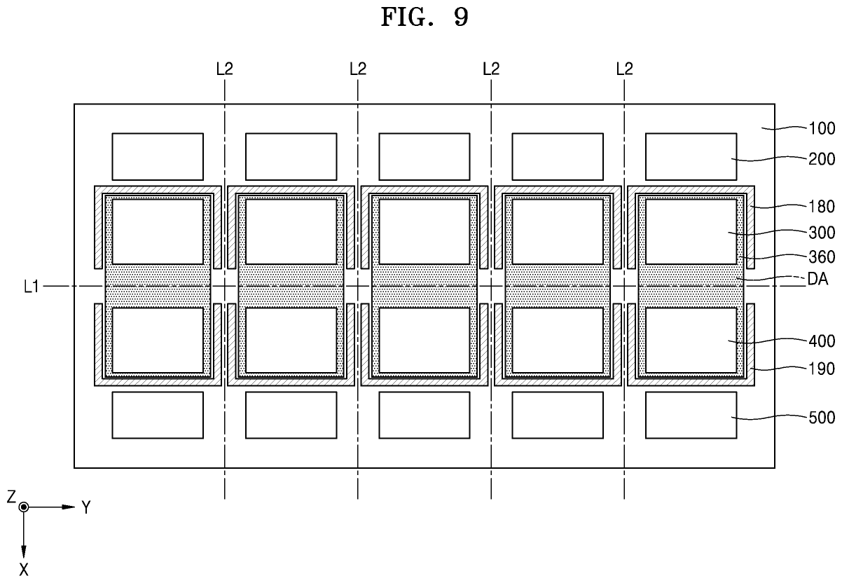

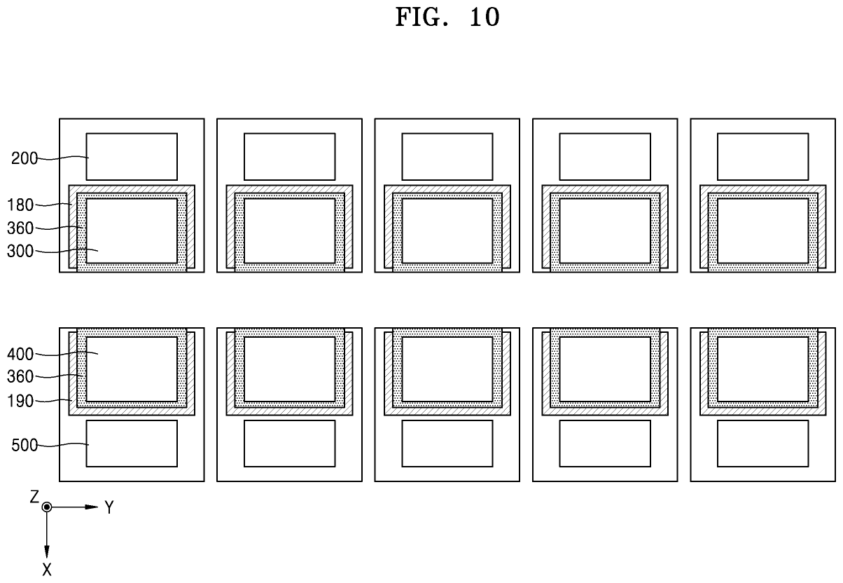

Referring to FIGS. 9 and 10, the first substrate 100 may be diced along a first line L1 crossing between the second chip structures 300 and the third chip structures 400 in the second horizontal direction Y after the underfill material layer 360 is formed.

According to some embodiments, the first substrate 100 may be curt along the first line L1, and the underfill material layer 360 may be separated in the first horizontal direction X. For example, a cross section of the underfill material layer 360 formed by dicing may form an angle of 90 degrees with the first substrate 100 in the vertical direction Z.

The first substrate 100 is cut along a second lines L2 extending in the first horizontal direction X after the first substrate 100 is cut along the first line L1. By cutting of the first substrate 100 above, as shown in FIG. 10, one first chip structure 200 and one second chip structure 300 may form one package, and one third chip structure 400 and one fourth chip structure 500 may form one package.

What is claimed is:

1. A semiconductor package comprising:
a first substrate;
a first chip structure disposed above the first substrate in a vertical direction;
a second chip structure disposed above the first substrate and spaced apart from the first chip structure in a first horizontal direction perpendicular to the vertical direction;
an underfill material layer disposed between the second chip structure and the first substrate; and
a first protrusion extending from the first substrate in the vertical direction and extending in a second horizontal direction perpendicular to the vertical direction and the first horizontal direction along at least one side surface of the underfill material layer,
wherein a side surface of the first protrusion contacts the underfill material layer.

2. The semiconductor package of claim 1, wherein a first sidewall of the underfill material layer is substantially perpendicular to an upper surface of the first substrate.

3. The semiconductor package of claim 1, wherein the first protrusion has a shape surrounding three of four side surfaces of the second chip structure in a plan view, excluding a side farthest from the first chip structure.

4. The semiconductor package of claim 1, wherein at least one side of the first protrusion is curved in a plan view.

5. The semiconductor package of claim 1, wherein a height of the first protrusion in the vertical direction is in a range between 10 μm and 20 μm.

6. The semiconductor package of claim 1, wherein the second chip structure includes a lower semiconductor chip and an upper semiconductor chip, and the lower semiconductor chip includes a through electrode extending in the vertical direction.

7. The semiconductor package of claim 1, wherein the first chip structure includes a memory device, and the second chip structure includes a logic device.

8. The semiconductor package of claim 1, wherein
the first substrate includes an interposer substrate, and
a package substrate is disposed on a lower portion of the first substrate.

9. The semiconductor package of claim 1, wherein
the first chip structure is mounted on the first substrate through a first bump,
the second chip structure includes a semiconductor chip mounted on a second substrate,
the second substrate is mounted on the first substrate through a second bump, and
the second bump is smaller than the first bump.

10. The semiconductor package of claim 9, wherein a passive component is mounted on a lower surface of the second substrate.

11. A semiconductor package comprising:
a first substrate;
a first chip structure disposed above the first substrate in a vertical direction;
a second chip structure disposed above the first substrate and spaced apart from the first chip structure in a first horizontal direction perpendicular to the vertical direction;
a third chip structure disposed above the first substrate and spaced apart from the first chip structure in the first horizontal direction, wherein the second chip structure is located between the first chip structure and the third chip structure;
an underfill material layer disposed between the second chip structure and the first substrate and between the third chip structure and the first substrate;
a first protrusion extending in the vertical direction; and
a second protrusion extending in the vertical direction,
wherein the first protrusion surrounds the second chip structure on three sides in a plan view and the second protrusion surrounds the third chip structure on three sides in the plan view.

12. The semiconductor package of claim 11, wherein at least one side of the first protrusion and the second protrusion is curved in a plan view.

13. The semiconductor package of claim 11, wherein the first protrusion and the second protrusion encapsulate the second chip structure and the third chip structure.

14. The semiconductor package of claim 11, wherein
the first chip structure is mounted on the first substrate through a first bump,
the second chip structure includes a semiconductor chip mounted on the second substrate,
the second substrate is mounted on the first substrate through a second bump located on the first substrate, the second bump is smaller than the first bump, and
a passive component is formed in a lower portion of the second substrate.

15. The semiconductor package of claim 14, wherein the second chip structure includes a lower semiconductor chip and an upper semiconductor chip, and the lower semiconductor chip includes a through electrode extending in the vertical direction.

16. The semiconductor package of claim 11, wherein a height of each of the first protrusion and the second protrusion in the vertical direction is between 10 μm and 20 μm.

17. The semiconductor package of claim 11, wherein the first chip structure includes a memory device, and the second chip structure includes a logic device.

18. A semiconductor package comprising:
a first substrate;
a first chip structure disposed above the first substrate in a vertical direction;
a second chip structure disposed above the first substrate and spaced apart from the first chip structure in a first horizontal direction perpendicular to the vertical direction;
a third chip structure disposed above the first substrate and spaced apart from the first chip structure in the first horizontal direction with the second chip structure disposed therebetween; and
an underfill material layer disposed between the second chip structure and the first substrate and between the third chip structure and the first substrate,
wherein the first substrate includes a first protrusion extending in a vertical direction and a second protrusion,
the first protrusion surrounds the second chip structure on three sides in a plan view and the second protrusion surrounds the third chip structure on three sides in the plan view,
an empty space is formed between the second chip structure and the third chip structure,
a height of each of the first protrusion and the second protrusion in the vertical direction is between 10 μm and 20 μm,
the first chip structure is mounted on the first substrate through a first bump,
the second chip structure includes a second substrate, wherein a semiconductor chip is mounted on the second substrate,
the second substrate is mounted on the first substrate through a second bump located on the first substrate, the size of the second bump is smaller than the size of the first bump, and
a passive component is formed on a lower portion of the second substrate.

19. The semiconductor package of claim 18, wherein the first chip structure includes a memory device, and the second chip structure includes a logic device.

20. The semiconductor package of claim 18, wherein at least one side of each of the first protrusion and the second protrusion is curved in a plan view.
